(19) United States
(12) Patent Application Publication
(10) Pub. No.: US 2007/0132090 A1
(43) Pub. Date: Jun. 14, 2007

(54) Semiconductor device

(75) Inventor: Kimihito Kuwabara, Kyoto (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/595,988

(22) Filed: Nov. 13, 2006

(30) Foreign Application Priority Data
Dec. 12, 2005 (JP) 2005-357076

(51) Int. Cl. H01L 23/12

(52) U.S. Cl. 257/700

(57) ABSTRACT

A semiconductor device (20) in which a semiconductor element (2) is mounted on one of a front side and a back side of a wiring board (3), and a plurality of lands (9)(23) for external connection are provided on the other side of the wiring board, the land (9)(23) including a land terminal (10)(24) formed on the wiring board and a spherical solder ball (11)(25) formed on the land terminal, wherein a first land (23) immediately below an outer end corner (B) of the semiconductor element (2) is larger in size than the other lands (9).

### FIELD OF THE INVENTION

The present invention relates to a semiconductor device for readily achieving high functionality and miniaturization of information communications equipment, office electronic equipment, and so on, and relates to a semiconductor device including a plurality of solder balls on the back side of a substrate (for example, a ball grid array (BGA) or a chip size package (CSP)

### BACKGROUND OF THE INVENTION

Conventionally, semiconductor devices are configured such that semiconductor elements are protected by semiconductor packages. The following is a main fabrication process of a semiconductor device. First, electrode terminals (pads) are formed with fine pitches on a surface of a semiconductor element. And then, the semiconductor element is mounted on a lead frame or an interposer circuit board having a multilayer interconnection structure. Thereafter, the electrode terminals of the semiconductor element are electrically connected to electrode lands on the lead frame or the interposer circuit board. The connecting method includes a wire bonding method using a thin metal wire and flip-chip method for forming metal bumps on electrode pads and directly bonding the metal bumps and the electrode lands together.

As will be discussed below, two methods are available for fixing a chip. In the wire bonding method, a chip and a lead frame are connected by adhesive paste or adhesive tape. In the flip-chip method, a chip and an interposer circuit board are sealed and fixed by an underfill material. Finally, the chip and the lead frame or the interposer circuit board are covered with thermosetting epoxy sealing resin and the resin is solidified. It is thus possible to protect metal wires, a chip, joints, and so on when using the wire bonding method. A semiconductor package is configured thus.

The semiconductor device fabricated thus makes up an electronic circuit board of an electrical product with other electronic components. In other words, the semiconductor device and so on are electrically connected to a printed wiring board by soldering, so that the electronic circuit board is formed. For this reason, a number of connection terminals for soldering are prepared for the semiconductor device.

In initial semiconductor packages, external electrodes are disposed on the four sides. In recent years, as the number of electrodes has increased in semiconductor products, mounting with higher density has been demanded. As a result, a semiconductor device has been developed in which a semiconductor element is mounted on one side of a wiring board (interposer circuit board) and a plurality of circular electrodes (referred to as lands) are arranged in a lattice pattern on the back side of the wiring board. Such a semiconductor package is called a land grid array (LGA) package. In some semiconductor packages, solder balls are formed on electrode lands and used as lands for connection to a printed wiring board. Such a package type is called a ball grid array (BGA). FIG. 22 shows a conventional semiconductor device featuring an area array layout of electrodes.

FIG. 22A is a front sectional view showing the configuration of a semiconductor device 1. FIG. 22B shows the semiconductor device taken along line X-X of FIG. 22A. A semiconductor element 2 shaped like a chip is bonded to the front side of an interposer circuit board 3 via connecting resin 4. The interposer circuit board 3 and a surface of an electronic circuit formed on the semiconductor element 2 are connected to each other via bonding wires 5 such as a metal wire. The semiconductor element 2 and the bonding wires 5 are sealed with mold sealing resin 6. The mold sealing resin 6 is made of epoxy resin and so on and has the function of protecting the semiconductor element 2 from external influence.

Further, on the back side of the interposer circuit board 3, a plurality of lands 9 for external connection are formed in rows and columns. The lands 9 are used for soldering to a printed wiring board (the circuit board of electronic equipment). The land 9 is made up of a circular land terminal 10 formed on the back side of the interposer circuit board 3 and a spherical solder ball 11 formed on the surface of the land terminal 10. The land terminal 10 and the solder ball 11 are equal in size. Further, the solder balls 11 are used for secondary mounting in which the semiconductor device 1 and the printed wiring board are connected to each other by soldering.

The following is the outline of a method of fabricating the semiconductor device 1.

First, the connecting resin 4 is applied or attached onto the interposer circuit board 3. And then, the semiconductor element 2 is mounted on the interposer circuit board 3 and the resin 4 is set, so that the mounting is completed. Thereafter, according to the wire bonding method, pads on the surface of the interposer circuit board 3 and pads on the surface of the electronic circuit formed on the semiconductor element 2 are connected to each other via the bonding wires 5. In some cases, a plurality of semiconductor elements are stacked. Finally, the semiconductor element 2 is sealed on the interposer circuit board 3 by transfer molding or the like.

However, in the configuration of the semiconductor device 1 of ball grid array type (BGA type) which has grown in number in recent years, the interposer circuit board 3 is soldered to the printed wiring board via the lands 9 for external connection and a solder joint to the land terminal 10 and the solder ball 11 may be broken due to stress caused by a difference in thermal expansion between the interposer circuit board 3 and the printed wiring board.

A distortion ε caused by the difference in thermal expansion can be roughly expressed by Equation 1 below:
εœ(α1-α2)×ΔT×L Equation 1
where α1 represents the thermal expansion coefficient of the interposer circuit board 3, α2 represents the thermal expansion coefficient of the printed wiring board, ΔT represents a temperature change during test or use, and L represents the size of the semiconductor device 1 (the interposer circuit board 3 or the semiconductor element 2).

In the semiconductor device 1, the mold sealing resin 6 and the interposer circuit board 3 are different in thermal expansion coefficient from the printed wiring board, so that a stress (=Young's modulus×distortion amount) occurs on the solder joints. Generally, the printed wiring board has a thermal expansion coefficient of about 16 to 25 ppm, whereas the mold sealing resin 6 has a thermal expansion coefficient of about 10 to 40 ppm and the interposer circuit board 3 has a thermal expansion coefficient of about 11 to 18 ppm. In the presence of a difference in thermal expansion coefficient (α1-α2) between the printed wiring board and the semiconductor device 1, the distortion εexpressed by Equation 1 occurs on the solder joints. The distortion εvaries among materials. The distortion ε is maximized at points where size L of the semiconductor device 1 is maximized, that is, near outermost corners A of the interposer circuit board 3. Thus the solder joints near the outermost corners A of the interposer circuit board 3 are broken.

Graph G1 (dotted line) of FIG. 23 shows the relationship between a distance from the center of the semiconductor device 1, in which the interposer circuit board 3 is made of ceramic, and a stress of the solder joint. According to the graph, the stress applied to the solder joint is maximized on the corners of the semiconductor device 1, that is, the outermost corners A of the interposer circuit board 3, so that the solder joints to the land terminals 10 and the solder balls 11 on the outermost corners A of the interposer circuit board 3 are first broken.

As a solution to the problem, in a proposed configuration of FIG. 24, lands 9a (that is, land terminals 10a and solder balls 11a) on outermost corners A of the interposer circuit board 3 are increased in size. For example, the land 9a on the outermost corner A is a circle formed by combining four (=two rows and two columns) of the lands 9 shown in FIG. 22B.

With this configuration, as indicated by graph G2 (solid line) of FIG. 23, a stress applied to solder joints is reduced on the corners of the semiconductor device 1, that is, the outermost corners A of the interposer circuit board 3. Thus it is possible to prevent a break on the solder joint of the outermost corner A.

Japanese Patent Laid-Open No. 11-26637 discloses a configuration in which ball lands and solder balls on the outermost corners of a substrate are increased in size.

Further, Japanese Patent Laid-Open No. 2000-100851 discloses a configuration in which a plurality of land terminals with bumps are formed on a semiconductor chip and the outer land terminals are larger in size than the inner land terminals.

Japanese Patent Laid-Open No. 11-317468 discloses a configuration in which land terminals and low-melting bumps on the outermost corners of a wiring board are increased in size. However, this configuration is designed to use, instead of thermal fatigue, a self alignment function using the surface tension of a molten metal. The self-alignment function makes it possible to align a number of bumps to predetermined positions. Thus stress concentration caused by thermal expansion on the corners is not taken into consideration and the use of low-melting solder results in a deterioration in thermal fatigue.

Japanese Patent Laid-Open No. 11-154718 discloses a configuration in which terminals and solder paste on the outermost corners of a package substrate are increased in size.

Generally, the semiconductor element 2 (chip) is fabricated with a thin-film circuit on a silicon crystal substrate. Silicon has an extremely small thermal expansion coefficient of about 3 ppm and thus a difference in thermal expansion coefficient is large between the printed wiring board and the semiconductor element 2 of the semiconductor device 1.

Conventionally, the interposer circuit board 3 for mounting the semiconductor element 2 has a relatively large thickness. Thus the hard semiconductor element 2 hardly affects the solder joints to the land terminals 10 and the solder balls 11 in a state in which the semiconductor device 1 is connected to the printed wiring board. As a result, the solder joints to the land terminals 10 and the solder balls 11 are hardly damaged near the semiconductor element 2.

However, in view of cost, the interposer circuit board 3 made of resin instead of ceramic has been frequently used in recent years. Moreover, the interposer circuit board 3 has been reduced in thickness to further reduce the thickness and weight of electronic equipment, so that the solder joints to the land terminals 10 and the solder balls 11 have been broken more and more by the influence of the semiconductor element 2 in a state in which the semiconductor device 1 is connected to the printed wiring board.

FIG. 25A is a front sectional view showing a semiconductor device 1 in which a semiconductor element 2 is smaller in size than an interposer circuit board 3. FIG. 25B is a plan view taken along line X-X of FIG. 25A. A land 9 immediately below the end of the semiconductor element 2 and another land 9 on the end of the interposer circuit board 3 are disposed on different positions.

The graph of FIG. 26 shows the relationship between a distance from the center of the semiconductor device 1 and a stress of a solder joint when the ceramic interposer circuit board 3 is used in the semiconductor device 1 of FIG. 25. According to the graph, the stress of the solder joint does not greatly fluctuates on an outer end corner B of the semiconductor element 2. However, a higher stress is applied to the solder joint on an outermost corner A of the interposer circuit board 3 due to stress singularity of the end face.

In contrast to FIG. 26, the graph of FIG. 27 shows the case where the material of the interposer circuit board 3 is changed from ceramic having a high hardness to soft resin. According to the graph, the stress of the solder joint immediately below the outer end corner B of the semiconductor element 2 is extremely high. This phenomenon similarly occurs also when the interposer circuit board 3 made of ceramic is reduced in thickness.

Graphs G1 (dotted lines) of FIGS. 26 and 27 show the case where a land 9a on the outermost corner A of the interposer circuit board 3 has the same size as the other lands 9. Graphs G2 (solid lines) show the case where the land 9a on the outermost corner A is larger in size than the other lands 9.

As shown in the graph of FIG. 27, when using the resin interposer circuit board 3, a high stress is applied to the solder joint immediately below the outer corner B of the semiconductor element 2, so that a solder joint to a land terminal 10 and a solder ball 11 immediately below the outer end corner B of the semiconductor element 2 is broken.

### DISCLOSURE OF THE INVENTION

An object of the present invention is to provide a semiconductor device which can prevent a stress caused by a difference in thermal expansion from breaking a solder joint to a land terminal and a solder ball immediately below an outer end corner of a semiconductor element in a state in which the land terminal is connected to the circuit board (printed wiring board) of electronic equipment via the solder ball.

A first invention is a semiconductor device comprising: a wiring board, a semiconductor element mounted on one of the front side and the back side of the wiring board, and a plurality of lands for external connection provided on the other side of the wiring board, the plurality of lands including a first land and other lands, each of the lands comprising a land terminal formed on the wiring board and a spherical solder ball formed on the land terminal, wherein the first land immediately below an outer end corner of the semiconductor element is larger in size than the other lands.

With this configuration, a solder joint to the land terminal and the solder ball of the first land has a larger cross-sectional area (bonding area) than solder joints to the land terminals and the solder balls of the other lands, thereby reducing a stress which is applied to the solder joint of the first land due to a difference in thermal expansion between the semiconductor device and the circuit board of electronic equipment. It is thus possible to prevent the solder joint of the first land immediately below the outer end corner of the semiconductor element from being broken, thereby increasing the life.

According to a second invention, in the semiconductor device of the first invention, a second land adjacent to the first land is larger in size than the other lands.

With this configuration, the first land is larger in size than the other lands, so that the size imbalance between the first land and the adjacent lands may cause stress concentration on the lands adjacent to the first land and the solder joints of the adjacent lands may be broken. In contrast to this configuration, the second land adjacent to the first land is larger in size than the other lands in the second invention, so that a solder joint to the land terminal and the solder ball of the second land has a larger cross-sectional area (bonding area) than the solder joints to the land terminals and the solder balls of the other lands. Thus in the event of stress concentration on the second land adjacent to the first land, it is possible to prevent the solder joint of the second land from being broken.

According to a third invention, in the semiconductor device of the first invention, the first land and the second lands disposed on both sides of the first land are bonded into a large land having a larger size than the other lands.

With this configuration, the first land and the second lands are bonded into the large land, so that a solder joint to the land terminal and the solder ball of the large land has a larger cross-sectional area (bonding area) than the solder joints to the land terminals and the solder balls of the other lands, thereby reducing a stress which is applied to the solder joint of the large land due to a difference in thermal expansion between the semiconductor device and the circuit board of electronic equipment.

Further, it is possible to obtain a long path distance when the solder joint to the land terminal and the solder ball of the large land is cracked by thermal fatigue. Thus the number of rupture/fatigue cycles until the occurrence of a break increases, so that a time period until the occurrence of a break is extended. It is therefore possible to prevent the solder joint of the large land immediately below the outer end corner of the semiconductor element from being broken, thereby increasing the life.

According to a fourth invention, in the semiconductor device of the first invention, a second land other than the first land is also larger in size than the other lands, the second land being disposed immediately below the line of the outer edge of the semiconductor element.

With this configuration, a solder joint to the land terminal and the solder ball of the second land has a larger cross-sectional area (bonding area) than the solder joints of the land terminals and the solder balls of the other lands, thereby reducing a stress which is applied to the solder joint of the second land due to a difference in thermal expansion between the semiconductor device and the circuit board of electronic equipment. It is therefore possible to prevent the solder joint of the first land immediately below the outer end corner of the semiconductor element from being broken and prevent the solder joint of the second land immediately below the line of the outer edge of the semiconductor element from being broken, thereby increasing the life.

According to a fifth invention, in the semiconductor device of the first invention, the wiring board is larger than the semiconductor element, and a third land on the outermost corner of the wiring board is larger in size than the other lands.

With this configuration, a solder joint to the land terminal and the solder ball of the third land has a larger cross-sectional area (bonding area) than solder joints to the land terminals and the solder balls of the other lands, thereby reducing a stress which is applied to the solder joint of the third land due to a difference in thermal expansion between the semiconductor device and the circuit board of electronic equipment. Therefore, it is possible to prevent the solder joint of the third land from being broken on the outermost corner of the wiring board.

According to a sixth invention, in the semiconductor device of the fifth invention, a fourth land adjacent to the third land is larger in size than the other lands.

With this configuration, another problem arises as follows: since the third land is larger in size than the other lands, the size imbalance between the third land and the adjacent lands may cause stress concentration on the lands adjacent to the third land and the solder joints of the adjacent lands may be broken. In contrast to this configuration, the fourth land adjacent to the third land is larger in size than the other lands in the sixth invention, so that a solder joint to the land terminal and the solder ball of the fourth land has a larger cross-sectional area (bonding area) than the solder joints to the land terminals and the solder balls of the other lands. Thus in the event of stress concentration on the fourth land adjacent to the third land, it is possible to prevent the solder joint of the fourth land from being broken.

According to a seventh invention, in the semiconductor device of the first invention, the wiring board is an organic substrate made of an organic resin.

According to an eighth invention, in the semiconductor device of the first invention, the wiring board has a thickness of 0.6 mm or less.

According to a ninth invention, in the semiconductor device according to the first invention, the first land is electrically disconnected from the semiconductor element.

With this configuration, even if excessive stress is applied to the first land and damages the first land, the stress does not interfere with the operations of an electric circuit.

A tenth invention is a semiconductor device comprising a wiring board, a semiconductor element mounted on one of the front side and the back side of a wiring board, and a plurality of lands for external connection, provided on the other side of the wiring board, the plurality of lands including a plurality of first lands and other lands, each land comprising a land terminal formed on the wiring board and a spherical solder ball formed on the land terminal, wherein the plurality of adjacent first lands immediately below the line of the outer edge of the semiconductor element are bonded into a land larger than the other lands.

With this configuration, the adjacent lands of the first lands are bonded into the large land, so that a solder joint to the land terminal and the solder ball of the large land has a larger cross-sectional area (bonding area) than solder joints to the land terminals and the solder balls of the other lands, thereby reducing a stress which is applied to the solder joint of the large land due to a difference in thermal expansion between the semiconductor device and the circuit board of electronic equipment. Therefore, it is possible to prevent the solder joint of the large land from being broken immediately below the outer end corner of the semiconductor element.

According to an eleventh invention, in the semiconductor device of the tenth invention, the wiring board is larger than the semiconductor element, and a third land on the outermost corner of the wiring board is larger in size than the other lands.

With this configuration, a solder joint to the land terminal and the solder ball of the third land has a larger cross-sectional area (bonding area) than solder joints to the land terminals and the solder balls of the other lands, thereby reducing a stress which is applied to the solder joint of the third land due to a difference in thermal expansion between the semiconductor device and the circuit board of electronic equipment. Therefore, it is possible to prevent the solder joint of the third land from being broken on the outermost corner of the wiring board.

According to a twelfth invention, in the semiconductor device of the eleventh invention, a fourth land adjacent to the third land is larger in size than the other lands.

With this configuration; the third land is larger in size than the other lands, so that the size imbalance between the third land and the adjacent lands may cause stress concentration on the lands adjacent to the third land and the solder joints of the adjacent lands may be broken. In contrast to this configuration, the fourth land adjacent to the third land is larger in size than the other lands in the twelfth invention, so that a solder joint to the land terminal and the solder ball of the fourth land has a larger cross-sectional area (bonding area) than solder joints to the land terminals and the solder balls of the other lands. Thus in the event of stress concentration on the fourth land adjacent to the third land, it is possible to prevent the solder joint of the fourth land from being broken.

According to a thirteenth invention, in the semiconductor device of the tenth invention, the wiring board has a thickness of not larger than 0.6 mm.

According to a fourteenth invention, in the semiconductor device of the tenth invention, the large land is electrically disconnected from the semiconductor element.

With this configuration, even if excessive stress is applied to the large land and damages the land, the stress does not interfere with the operations of an electric circuit.

A fifteenth invention is a semiconductor device comprising: wiring board; a semiconductor element mounted on one of the front side and the back side of a wiring board; and a plurality of lands for external connection, provided on the other side of the wiring board, the plurality of lands including a plurality of first lands and other lands, each land comprising a land terminal formed on the wiring board and a spherical solder ball formed on the land terminal, wherein the plurality of first lands disposed near the outer end corners of the semiconductor element and inside or outside the line of the outer edge of the semiconductor element are larger in size than the other lands.

With this configuration, a solder joint to the land terminal and the solder ball of the first land has a larger cross-sectional area (bonding area) than solder joints to the land terminals and the solder balls of the other lands, thereby reducing a stress which is applied to the solder joint of the first land due to a difference in thermal expansion between the semiconductor device and the circuit board of electronic equipment. Therefore, it is possible to prevent the solder joint of the first land immediately below the outer end corner of the semiconductor element from being broken.

According to the sixteenth invention, in the semiconductor device of the fifteenth invention, the wiring board is larger than the semiconductor element, and a third land on the outermost corner of the wiring board is larger in size than the other lands.

With this configuration, a solder joint to the land terminal and the solder ball of the third land has a larger cross-sectional area (bonding area) than solder joints to the land terminals and the solder balls of the other lands, thereby reducing a stress which is applied to the solder joint of the third land due to a difference in thermal expansion between the semiconductor device and the circuit board of electronic equipment. Therefore, it is possible to prevent the solder joint of the third land from being broken on the outermost corner of the wiring board.

According to the seventeenth invention, in the semiconductor device of the sixteenth invention, a fourth land adjacent to the third land is larger in size than the other lands.

With this configuration, the third land is larger in size than the other lands, so that the size imbalance between the third land and the adjacent lands may cause stress concentration on the lands adjacent to the third land and the solder joints of the adjacent lands may be broken. In contrast to this configuration, the fourth land adjacent to the third land is larger in size than the other lands in the seventeenth invention, so that a solder joint to the land terminal and the solder ball of the fourth land has a larger cross-sectional area (bonding area) than the solder joints of the land terminals and the solder balls of the other lands. Thus in the event of stress concentration on the fourth land adjacent to the third land, it is possible to prevent the solder joint of the fourth land from being broken.

According to the eighteenth invention, in the semiconductor device of the fifteenth invention, the wiring board has a thickness of 0.6 mm or less.

According to the nineteenth invention, in the semiconductor device of the fifteenth invention, the first land is electrically disconnected from the semiconductor element.

With this configuration, even if excessive stress is applied to the first land and damages the land, the stress does not interfere with the operations of an electric circuit.

### BRIEF DESCRIPTION OF THE DRAWINGS

FIG. 1 shows a semiconductor device according to Embodiment 1 of the present invention, wherein FIG. 1A is a front sectional view and FIG. 1B is a plan view taken along line X-X of FIG. 1A;

FIG. 2 is a sectional view showing that the semiconductor device of Embodiment 1 is connected to a printed wiring board;

FIG. 3 is a graph showing the relationship between a distance from the center of the semiconductor device and a stress of a solder joint according to Embodiment 1;

FIG. 4 is a plan view showing a semiconductor device according to Embodiment 2 of the present invention;

FIG. 5 is a plan view showing a semiconductor device according to Embodiment 3 of the present invention;

FIG. 6 is a plan view showing a semiconductor device according to Embodiment 4 of the present invention;

FIG. 7 is a plan view showing a semiconductor device according to Embodiment 5 of the present invention;

FIG. 8 shows a semiconductor device according to Embodiment 6 of the present invention, wherein FIG. 8A is a front sectional view and FIG. 8B is a plan view taken along line X-X of FIG. 8A;

FIG. 9 is a plan view showing a semiconductor device according to Embodiment 7 of the present invention;

FIG. 10 is a plan view showing a semiconductor device according to Embodiment 8 of the present invention;

FIG. 11 is a plan view showing a semiconductor device according to Embodiment 9 of the present invention;

FIG. 12 is a plan view showing a semiconductor device according to Embodiment 10 of the present invention;

FIG. 13 is a plan view showing a semiconductor device according to Embodiment 11 of the present invention;

FIG. 14 is a plan view showing a semiconductor device according to Embodiment 12 of the present invention;

FIG. 15 is a plan view showing a semiconductor device according to Embodiment 13 of the present invention;

FIG. 16 is a plan view showing a semiconductor device according to Embodiment 14 of the present invention;

FIG. 17 is a plan view showing a semiconductor device according to Embodiment 15 of the present invention;

FIG. 18 is a plan view showing a semiconductor device according to Embodiment 16 of the present invention;

FIG. 19 shows a semiconductor device according to Embodiment 17 of the present invention, wherein FIG. 19A is a front sectional view and FIG. 19B is a plan view taken along line X-X of FIG. 19A;

FIG. 20 is a plan view showing a semiconductor device according to Embodiment 18 of the present invention;

FIG. 21 is a sectional view showing a semiconductor device according to Embodiment 21 of the present invention;

FIG. 22 shows a conventional semiconductor device including lands of uniform size, wherein FIG. 22A is a front sectional view and FIG. 22B is a plan view taken along line X-X of FIG. 22A;

FIG. 23 is a graph showing the relationship between a distance from the center of the conventional semiconductor device and a stress of a solder joint;

FIG. 24 is a plan view showing a conventional semiconductor device in which lands are increased in size on the outermost corners of an interposer circuit board;

FIG. 25 shows a conventional semiconductor device in which a semiconductor element is smaller in size than an interposer circuit board, wherein FIG. 25A is a front sectional view and FIG. 25B is a plan view taken along line X-X of FIG. 25A;

FIG. 26 is a graph showing the relationship between a distance from the center of the conventional semiconductor device and a stress of a solder joint, the semiconductor device using a ceramic interposer circuit board; and

FIG. 27 is a graph showing the relationship between a distance from the center of the conventional semiconductor device and a stress of the solder joint, the semiconductor device using a resin interposer circuit board.

### DESCRIPTION OF THE EMBODIMENTS

The present invention will be specifically described below in accordance with the accompanying drawings. Members having the same configurations as those of the conventional semiconductor device are indicated by the same reference numerals and the explanation thereof is omitted.

### Embodiment 1

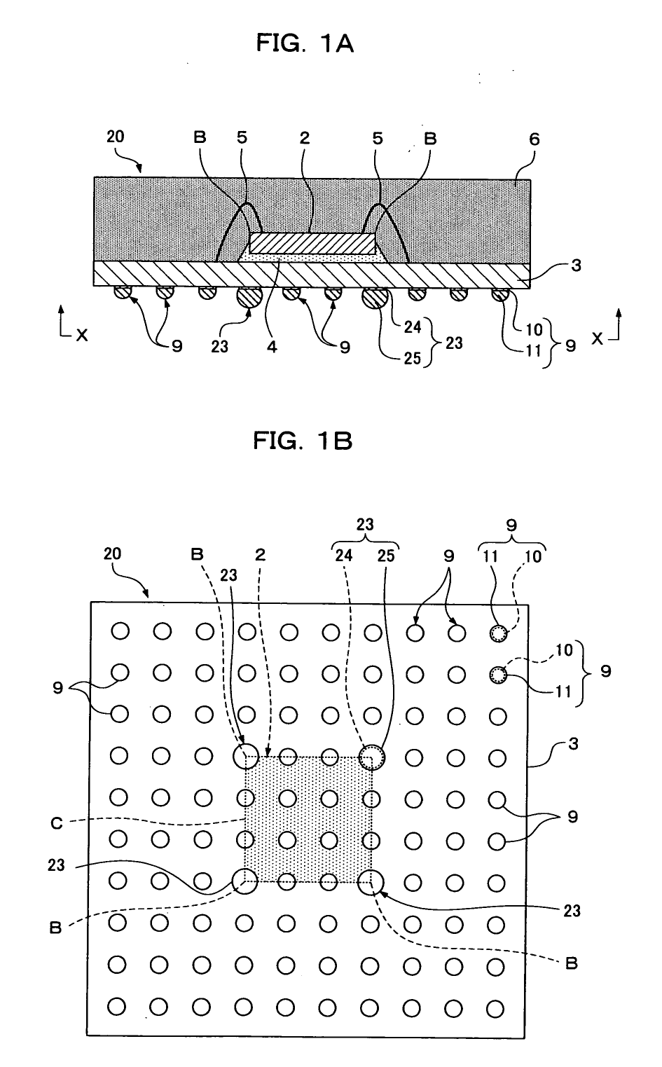

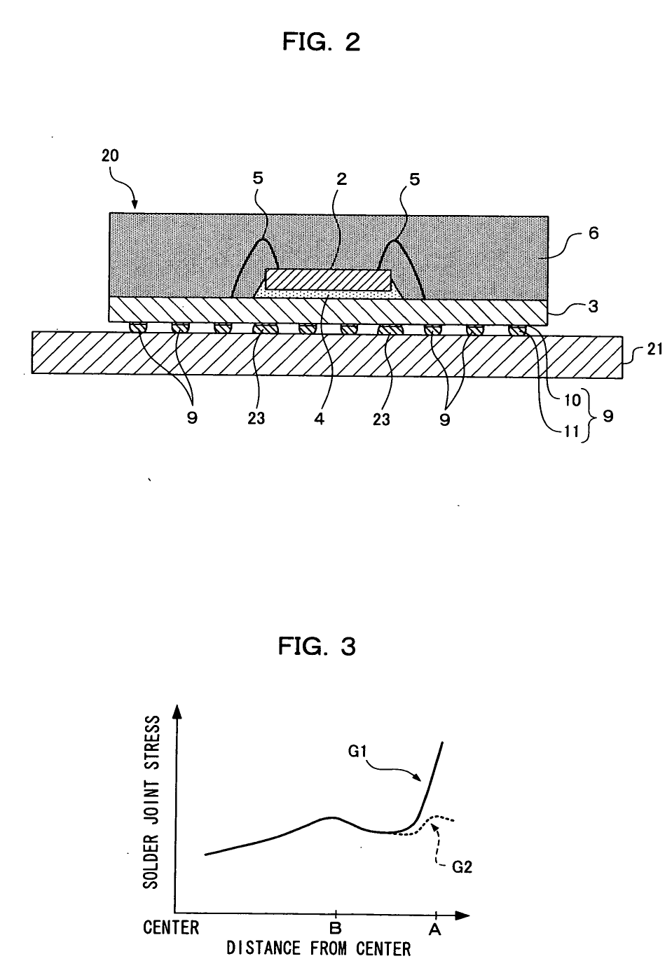

First, Embodiment 1 of the present invention will be described below. FIG. 1A is a front sectional view showing a semiconductor device 20. FIG. 1B is a plan view taken along line X-X of FIG. 1A. FIG. 2 is a sectional view showing that the semiconductor device 20 is mounted and connected onto a printed wiring board 21.

A semiconductor element 2 is mounted on one of the surfaces of an interposer circuit board 3 which is larger in size than the semiconductor element 2. Further, a plurality of lands 9 and 23 for external connection are disposed on the other surface of the interposer circuit board 3. The lands 9 and 23 are respectively made up of land terminals 10 and 24 formed on the interposer circuit board 3 and spherical solder balls 11 and 25 formed on the land terminals 10 and 24.

Of these lands, first land 23 immediately below four outer end corners B of the semiconductor element 2 are larger in size than the other lands 9. To be specific, the land terminals 24 of the first lands 23 are larger in diameter than the land terminals 10 of the other lands 9, and the solder balls 25 of the first lands 23 are larger in diameter and height than the solder balls 11 of the other lands 9.

The following will describe the operation of the configuration.

A solder joint to the land terminal 24 and the solder ball 25 of the first land 23 has a larger cross-sectional area than solder joints to the land terminals 10 and the solder balls 11 of the other lands 9, thereby reducing a stress which is applied to the solder joint of the first land 23 due to a difference in thermal expansion between the semiconductor device 20 and the printed wiring board 21. It is therefore possible to prevent the solder joint of the first land 23 from being broken immediately below the outer end corner B of the semiconductor element 2, thereby increasing the life.

The cross-sectional area of the solder joint is an area of a cross section paralleling with the other surface of the interposer circuit board 3 and is equivalent to a bonding area.

Graph G1 (solid line) of FIG. 3 shows the relationship between a distance from the center of the semiconductor device 20 and a stress of the solder joint. As compared with the conventional semiconductor device (see the graph of FIG. 27), the solder joint immediately below the outer end corner B of the semiconductor element 2 has a lower stress.

In Embodiment 1, the first lands 23 are electrically connected to the semiconductor element 2. The first lands 23 may be electrically disconnected (in other words, the first lands 23 may not be electrically connected to the semiconductor element 2). With this configuration, even if excessive stress is applied to the first land 23 and damages the land, the function of an electric circuit is maintained.

### Embodiment 2

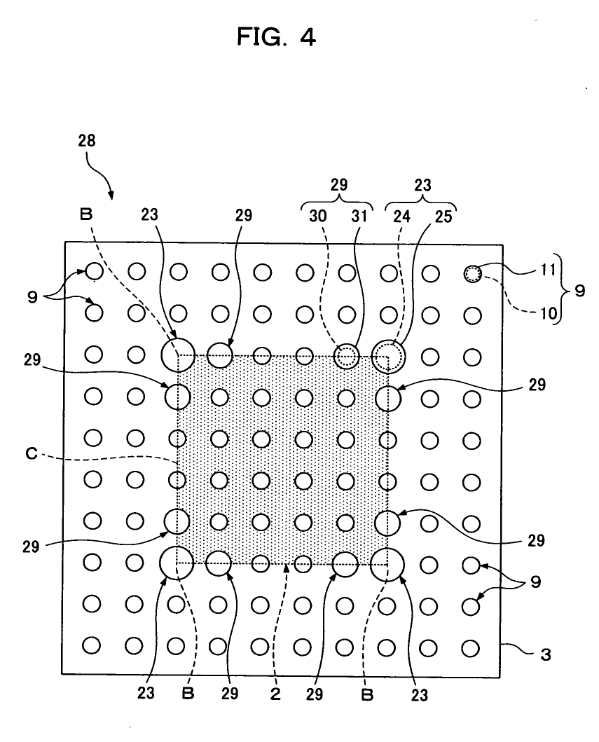

Embodiment 2 of the present invention will be described below. FIG. 4 shows an interposer circuit board 3 of a semiconductor device 28. The interposer circuit board 3 is viewed from the other surface (back side).

In addition to the size of first lands 23, second lands 29 on both sides of the first land 23 are larger in size than other lands 9. To be specific, land terminals 30 of the second lands 29 are larger in diameter than land terminals 10 of the other lands 9, and solder balls 31 of the second lands 29 are larger in diameter and height than solder balls 11 of the other lands 9.

In the configuration shown in FIG. 1 of Embodiment 1, another problem arises as follows: since the first land 23 is larger in size than the other lands 9, the size imbalance between the first land 23 and the adjacent lands 9 may cause stress concentration on the other lands 9 adjacent to the first land 23 and the solder joints of the adjacent lands 9 may be broken.

In contrast to Embodiment 1, as shown in FIG. 4, the second lands 29 adjacent to the first land 23 are larger in size than the other lands 9, so that a solder joint to the land terminal 30 and the solder ball 31 of the second land 29 has a larger cross-sectional area than solder joints to the land terminals 10 and the solder balls 11 of the other lands 9. Thus in the event of stress concentration on the second land 29 adjacent to the first land 23, it is possible to prevent the solder joint of the second land 29 from being broken.

In Embodiment 2, the first and second lands 23 and 29 are electrically connected to the semiconductor element 2. The first and second lands 23 and 29 may be electrically disconnected (in other words, the first and second lands 23 and 29 may not be electrically connected to the semiconductor element 2). With this configuration, even if excessive stress is applied to the first lands 23 and the second lands 29 and damages the lands, the function of an electric circuit is maintained. Only one of the first land 23 and the second land 29 may be electrically disconnected.

### Embodiment 3

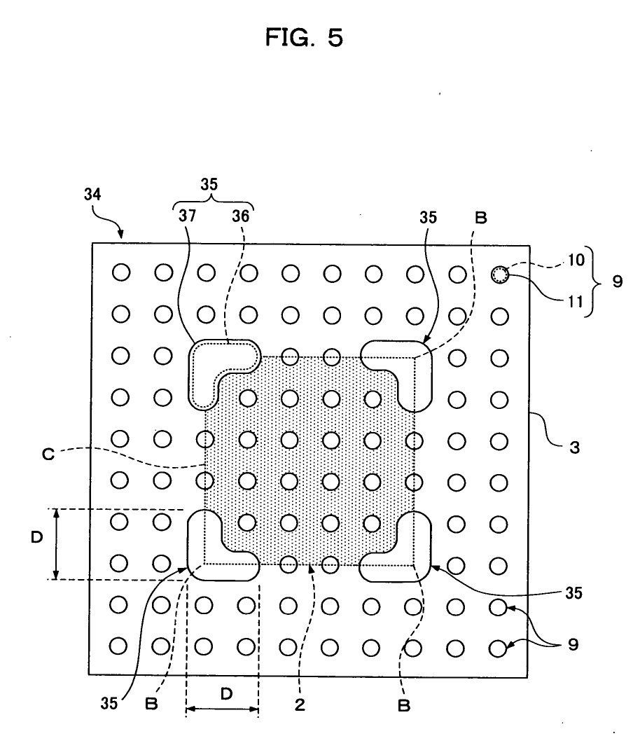

Embodiment 3 of the present invention will be described below. FIG. 5 shows an interposer circuit board 3 of a semiconductor device 34. The interposer circuit board 3 is viewed from the other surface.

As shown in FIG. 5, a first land 23 (FIG. 4) immediately below each of four outer end corners B of a semiconductor element 2 and second lands 29 (FIG. 4) on both sides of the first land 23 are bonded into a large land 35 which is shaped like a letter L (like a key). The large land 35 is larger in size than other lands 9. To be specific, a land terminal 36 of the large land 35 is shaped like a letter L and has a larger area than land terminals 10 of the other lands 9. Further, a solder ball 37 of the large land 35 is shaped like a letter L and has a larger area than solder balls 11 of the other lands 9.

With this configuration, a solder joint to the land terminal 36 and the solder ball 37 of the large land 35 has a larger cross-sectional area than solder joints to the land terminals 10 and the solder balls 11 of the other lands 9, thereby reducing a stress which is applied to the solder joint of the large land 35 due to a difference in thermal expansion between the semiconductor device 34 and a printed wiring board 21.

Further, it is possible to obtain a long path distance D when the solder joint to the land terminal 36 and the solder ball 37 of the large land 35 are cracked by thermal fatigue developing from the outer periphery. Thus the number of rupture/fatigue cycles until the occurrence of a break increases, so that a time period until the occurrence of a break is extended. It is therefore possible to prevent the solder joint of the large land 35 from being broken immediately below the outer end corners B of the semiconductor element 2, thereby increasing the life.

In Embodiment 3, the large lands 35 are electrically connected to the semiconductor element 2. The large lands 35 may be electrically disconnected (in other words, the large lands 35 may not be electrically connected to the semiconductor element 2). With this configuration, even if excessive stress is applied to the large land 35 and damages the land, the function of an electric circuit is maintained.

### Embodiment 4

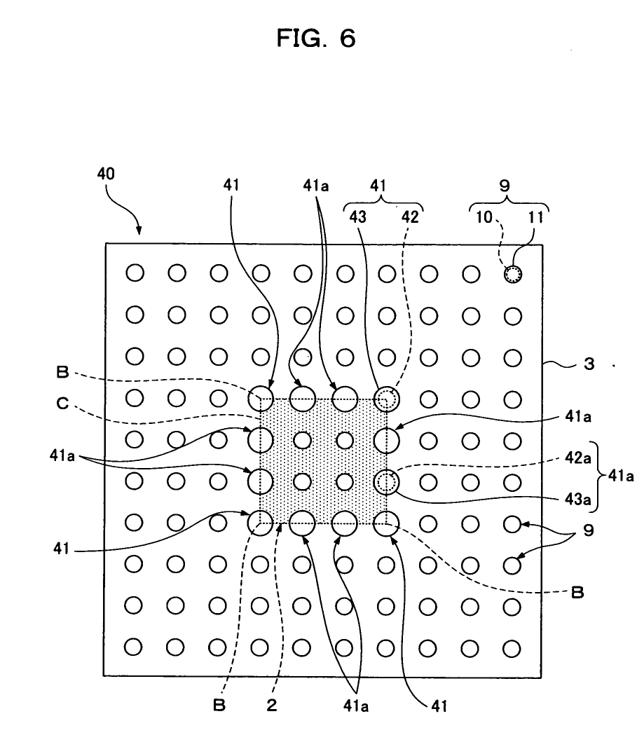

Embodiment 4 of the present invention will be described below. FIG. 6 shows an interposer circuit board 3 of a semiconductor device 40. The interposer circuit board 3 is viewed from the other surface.

Second lands 41a other than first lands 41 are also larger in size than other lands 9. The second lands 41a are disposed immediately below lines C on the outer edges of the four sides of a semiconductor element 2. The first lands 41 are disposed immediately below outer end corners B of the semiconductor element 2 and the second lands 41a are interposed between the first lands 41. The second lands 41a are larger in size than the other lands 9 and equal in size to the first lands 41.

To be specific, land terminals 42a of the second lands 41a are larger in diameter than land terminals 10 of the other lands 9 and equal in diameter to land terminals 42 of the first lands 41. Further, solder balls 43a of the second lands 41a are larger in diameter and height than solder balls 11 of the other lands 9 and equal in diameter and height to solder balls 43 of the first lands 41.

With this configuration, a solder joint to the land terminal 42 and the solder ball 43 of the first land 41 has a larger cross-sectional area than solder joints to the land terminals 10 and the solder balls 11 of the other lands 9. Further, a solder joint to the land terminal 42a and the solder ball 43a of the second land 41a has a larger cross-sectional area than the solder joints to the land terminals 10 and the solder balls 11 of the other lands 9.

It is thus possible to reduce a stress applied to the solder joint of the first land 41 and a stress applied to the solder joint of the second land 41a. These stresses are caused by a difference in thermal expansion between the semiconductor device 40 and a printed wiring board 21. Therefore, it is possible to prevent the solder joint of the first land 41 from being broken immediately below the outer end corner B of the semiconductor element 2 and prevent the solder joint of the second land 41a from being broken immediately below the line C, thereby increasing the life.

In Embodiment 4, the first and second lands 41 and 41a are electrically connected to the semiconductor element 2. The first and second lands 41 and 41a may be electrically disconnected (in other words, the first and second lands 41 and 41a may not be electrically connected to the semiconductor element 2). Therefore, even if excessive stress is applied to the first and second lands 41 and 41a and damages the lands, the function of an electric circuit is maintained. Only one of the first land 41 and the second land 41a may be electrically disconnected.

### Embodiment 5

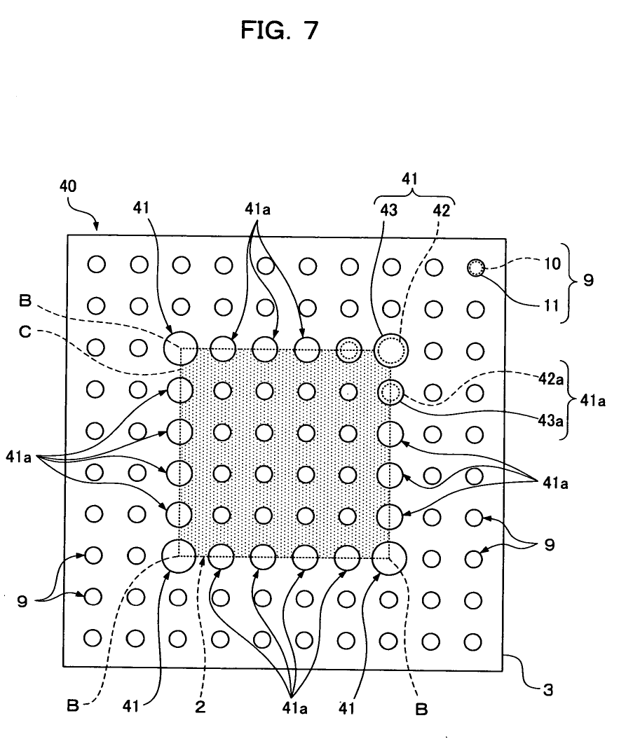

Embodiment 5 of the present invention will be described below. FIG. 7 shows an interposer circuit board 3 of a semiconductor device 40. The interposer circuit board 3 is viewed from the other surface.

Second lands 41a other than first lands 41 are also larger in size than other lands 9. The second lands 41a are disposed immediately below lines C on the outer edges of the four sides of a semiconductor element 2. The first lands 41 are disposed immediately below outer end corners B of the semiconductor element 2 and the second lands 41a are interposed between the first lands 41. The second lands 41a are larger in size than the other lands 9 and smaller in size than the first lands 41.

To be specific, land terminals 42a of the second lands 41a are larger in diameter than land terminals 10 of the other lands 9 and smaller in diameter than land terminals 42 of the first lands 41. Further, solder balls 43a of the second lands 41a are larger in diameter and height than solder balls 11 of the other lands 9 and smaller in diameter and height than solder balls 43 of the first lands 41.

With this configuration, a solder joint to the land terminal 42 and the solder ball 43 of the first land 41 has a larger cross-sectional area than solder joints to the land terminals 10 and the solder balls 11 of the other lands 9. Further, a solder joint to the land terminal 42a and the solder ball 43a of the second land 41a has a larger cross-sectional area than the solder joints to the land terminals 10 and the solder balls 11 of the other lands 9.

Thus, it is possible to reduce a stress applied to the solder joint of the first land 41 and a stress applied to the solder joint of the second land 41a. These stresses are caused by a difference in thermal expansion between the semiconductor device 40 and a printed wiring board 21. It is therefore possible to prevent the solder joint of the first land 41 from being broken immediately below the outer end corner B of the semiconductor element 2 and prevent the solder joint of the second land 41a from being broken immediately below the line C, thereby increasing the life.

In Embodiment 5, the first and second lands 41 and 41a are electrically connected to the semiconductor element 2. The first and second lands 41 and 41a may be electrically disconnected (in other words, the first and second lands 41 and 41a may not be electrically connected to the semiconductor element 2). With this configuration, even if excessive stress is applied to the first and second lands 41 and 41a and damages the lands, the function of an electric circuit is maintained. Only one of the first land 41 and the second land 41a may be electrically disconnected.

### Embodiment 6

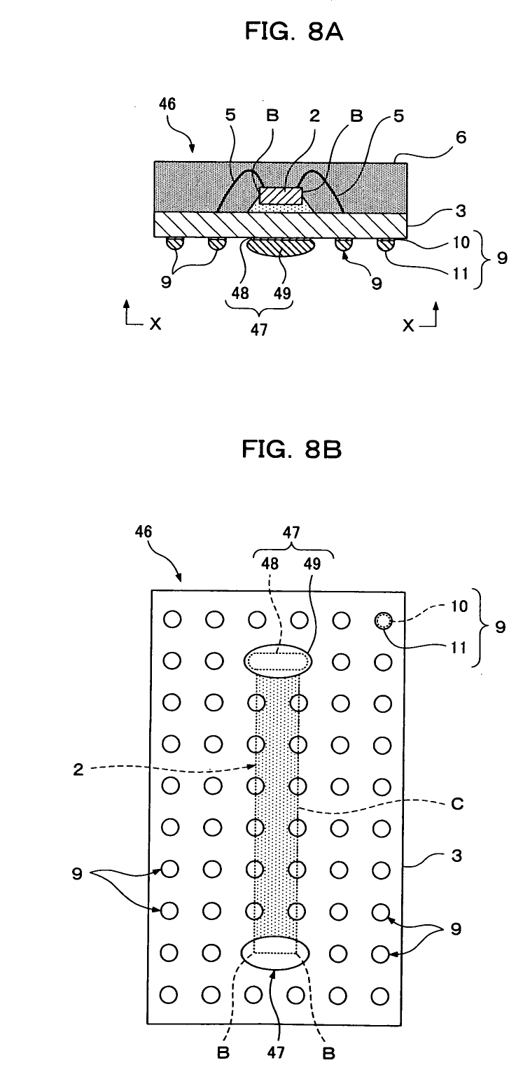

Embodiment 6 of the present invention will be described below. FIG. 8A is a front sectional view showing a semiconductor device 46. FIG. 8B is a plan view taken along line X-X of FIG. 8A.

As shown in FIG. 8B, immediately below two opposite lines of lines C on the outer edges of the four sides of a semiconductor element 2, two or more first lands 41 adjacent to each other are bonded into large oval lands 47. The large land 47 is larger in size than the other lands 9. To be specific, a land terminal 48 of the large land 47 is shaped like an ellipse and has a larger area than land terminals 10 of the other lands 9. Further, a solder ball 49 of the large land 47 is shaped like an ellipse and has a larger area than solder balls 11 of the other lands 9.

With this configuration, a solder joint to the land terminal 48 and the solder ball 49 of the large land 47 has a larger cross-sectional area than solder joints to the land terminals 10 and the solder balls 11 of the other lands 9, thereby reducing a stress which is applied to the solder joint of the large land 47 due to a difference in thermal expansion between the semiconductor device 46 and a printed wiring board 21. It is therefore possible to prevent the solder joint of the first land 47 from being broken immediately below outer end corners B of the semiconductor element 2.

In Embodiment 6, the large lands 47 are electrically connected to the semiconductor element 2. The large lands 47 may be electrically disconnected (in other words, the large lands 47 may not be electrically connected to the semiconductor element 2). With this configuration, even if excessive stress is applied to the large lands 47 and damages the lands, the function of an electric circuit is maintained.

In Embodiment 6, the two lands are bonded into the large land 47. Three or more lands may be bonded into the large land 47.

### Embodiment 7

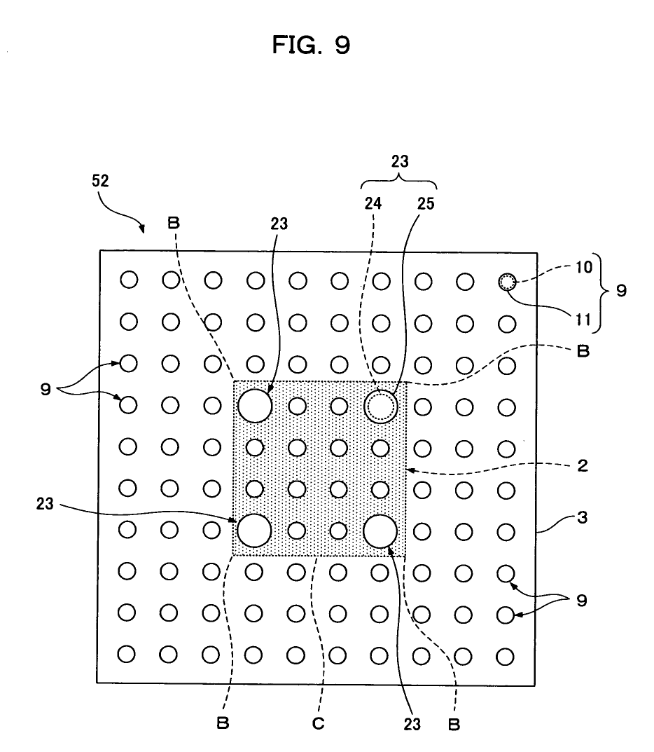

Embodiment 7 the present invention will be described below. FIG. 9 shows an interposer circuit board 3 of a semiconductor device 52. The interposer circuit board 3 is viewed from the other surface.

In the semiconductor device 52 of Embodiment 7, the first lands 23 similar to those of Embodiment 1 (FIG. 1) are disposed inside lines C of the outer edges of a semiconductor element 2.

With this configuration, it is possible to prevent the solder joint of the first land 23 immediately below an outer end corners B of the semiconductor element 2 from being broken.

### Embodiments 8 to 11

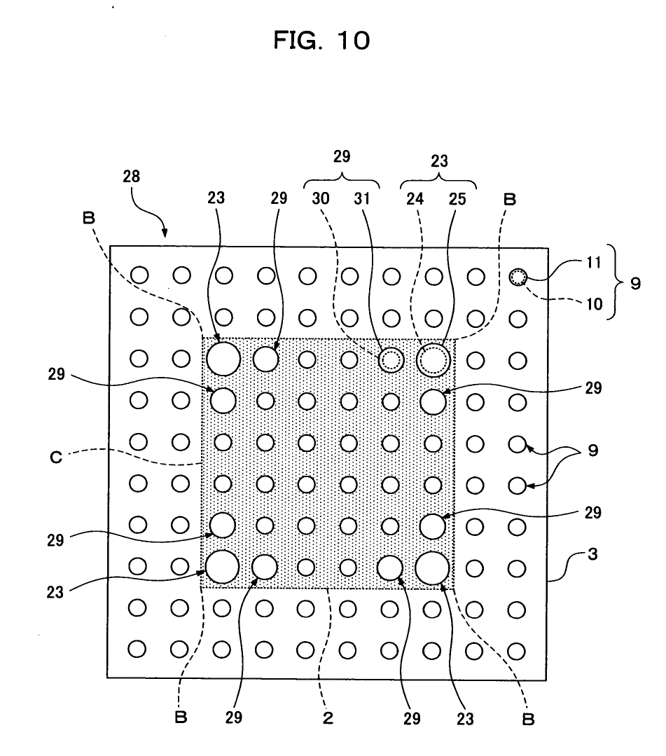

Embodiments 8 to 11 of the present invention will be described below. As shown in FIGS. 10 to 13, first lands 23 and 41, second lands 29 and 41a, and large land 35 which are similar to those of Embodiments 2 to 5 (FIGS. 4 to 7) are disposed inside lines C of the outer edges of a semiconductor element 2.

With this configuration, in a semiconductor device 28 of Embodiment 8 shown in FIG. 10, it is possible to prevent the solder joint of the first land 23 from being broken immediately below an outer end corner B of the semiconductor element 2. Further, in the event of stress concentration on the second land 29 adjacent to the first land 23, it is possible to prevent the solder joint of the second land 29 from being broken.

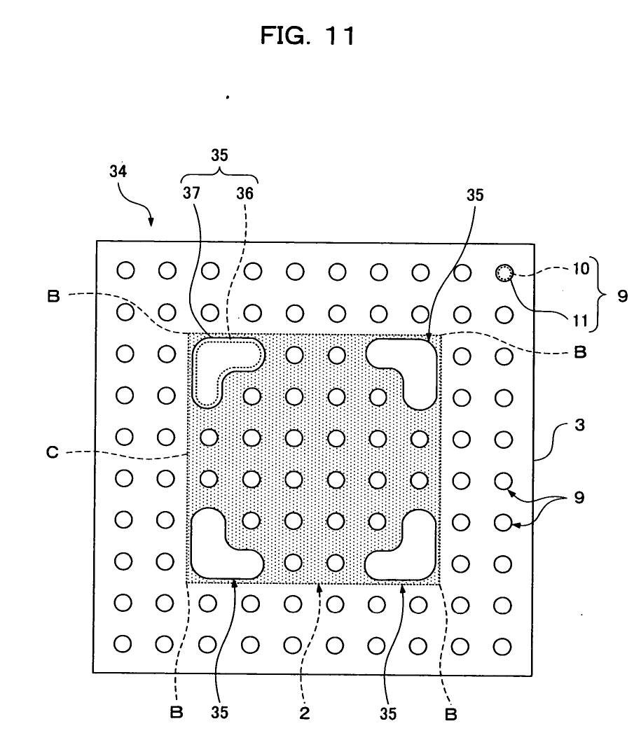

In a semiconductor device 34 of Embodiment 9 shown in FIG. 11, it is possible to prevent the solder joint of the large land 35 from being broken immediately below an outer end corner B of the semiconductor element 2.

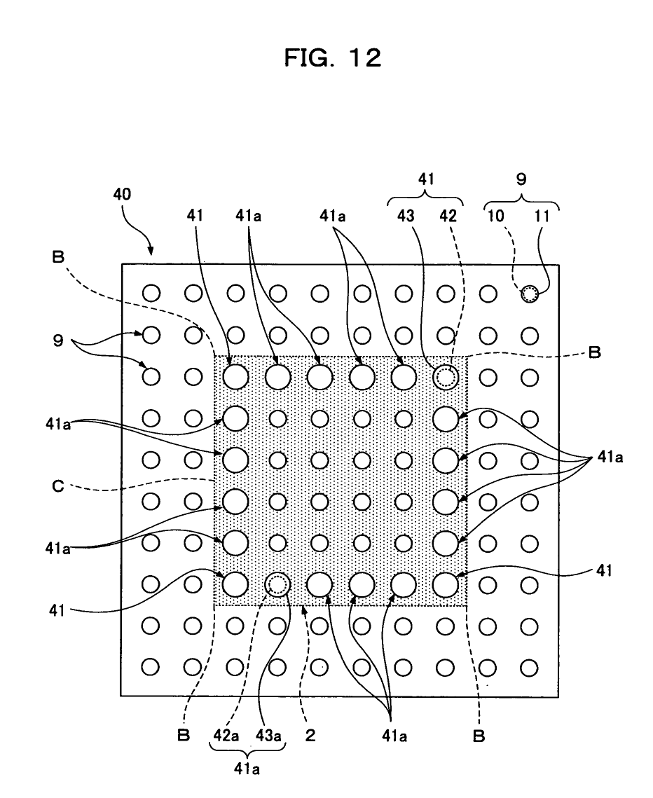

In a semiconductor device 40 of Embodiment 10 shown in FIG. 12, it is possible to prevent the solder joint of the first land 41 from being broken immediately below an outer end corner B of the semiconductor element 2 and prevent the solder joint of the second land 41a from being broken inside the line C.

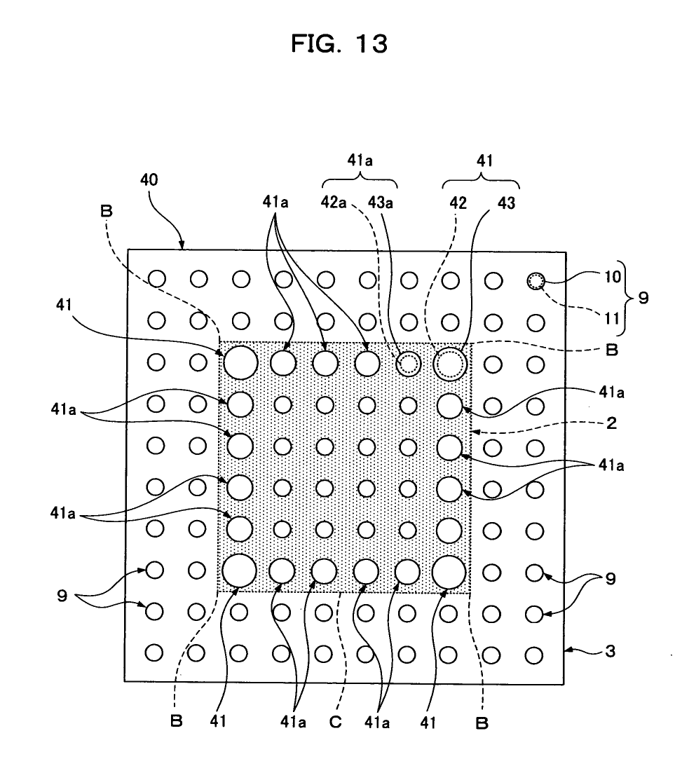

In a semiconductor device 40 of Embodiment 11 shown in FIG. 13, it is possible to prevent the solder joint of the first land 41 from being broken immediately below an outer end corner B of the semiconductor element 2 and prevent the solder joint of the second land 41a from being broken inside the line C.

### Embodiment 12

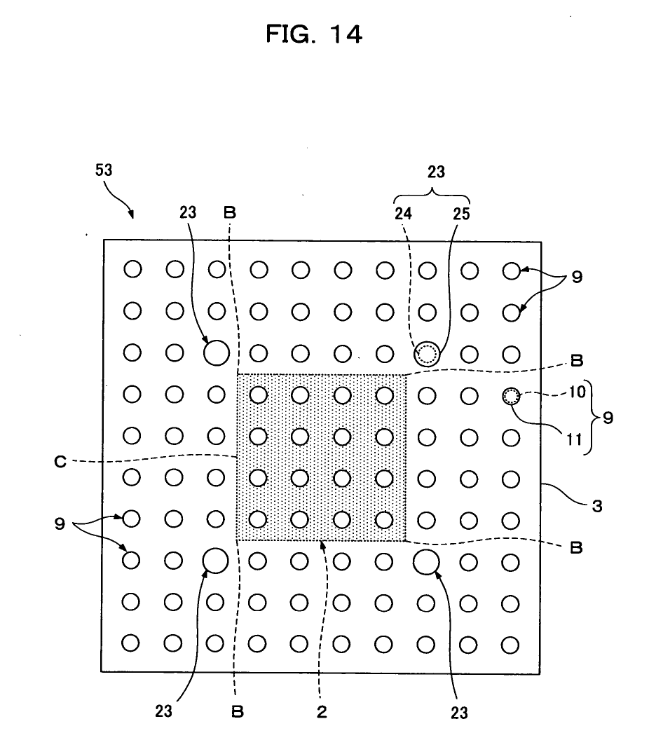

Embodiment 12 of the present invention will be described below. FIG. 14 shows an interposer circuit board 3 of a semiconductor device 53. The interposer circuit board 3 is viewed from the other surface.

In the semiconductor device 53 of Embodiment 12, first lands 23 similar to those of Embodiment 1 (FIG. 1) are disposed outside lines C of the outer edges of a semiconductor element 2.

With this configuration, it is possible to prevent the solder joint of the first land 23 from being broken immediately below an outer end corner B of the semiconductor element 2.

### Embodiments 13 to 16

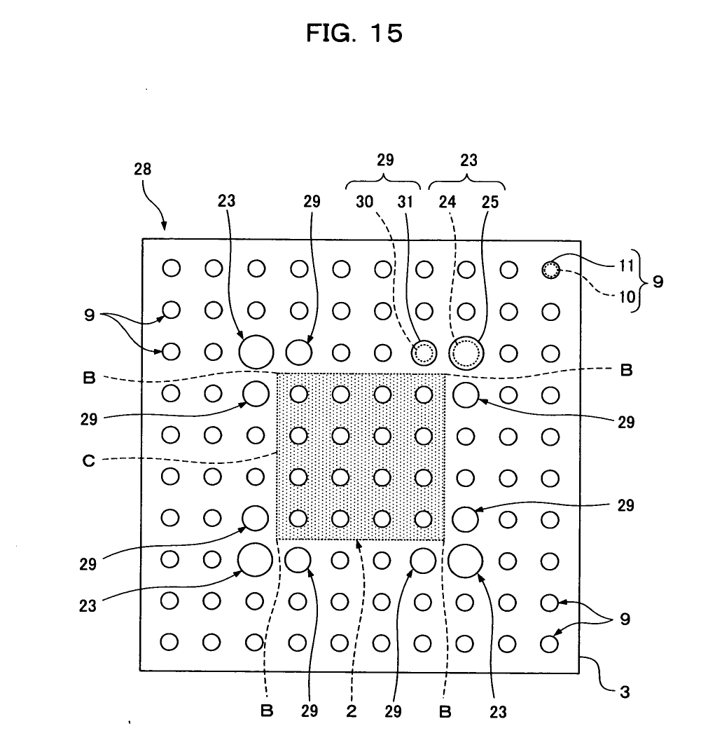

Embodiments 13 to 16 of the present invention will be described below. As shown in FIGS. 15 to 18, first lands 23 and 41, second lands 29 and 41a, and large lands 35 which are similar to those of Embodiments 2 to 5 (FIGS. 4 to 7) are disposed outside lines C of the outer edges of a semiconductor element 2.

With this configuration, in a semiconductor device 28 of Embodiment 13 shown in FIG. 15, it is possible to prevent the solder joint of the first land 23 from being broken immediately below an outer end corner B of the semiconductor element 2. Further, in the event of stress concentration on the second land 29 adjacent to the first land 23, it is possible to prevent the solder joint of the second land 29 from being broken.

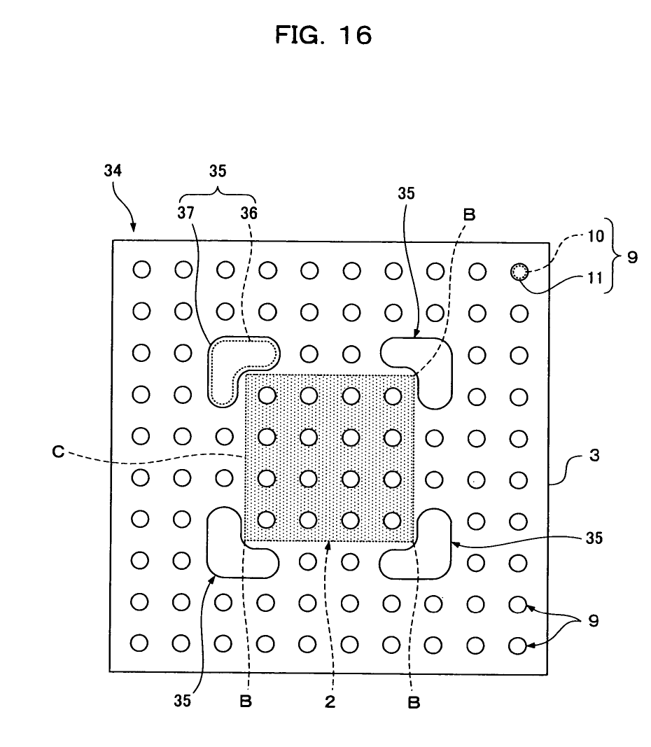

In a semiconductor device 34 of Embodiment 14 shown in FIG. 16, it is possible to prevent the solder joint of the large land 35 from being broken immediately below an outer end corner B of the semiconductor element 2.

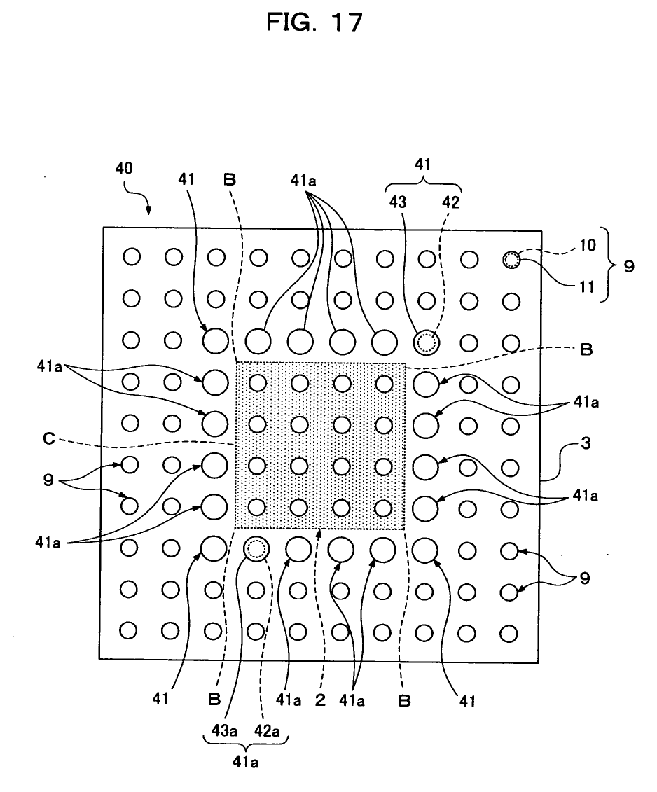

In a semiconductor device 40 of Embodiment 15 shown in FIG. 17, it is possible to prevent the solder joint of the first land 41 from being broken immediately below an outer end corner B of the semiconductor element 2 and prevent the solder joint of the second land 41a from being broken outside the line C.

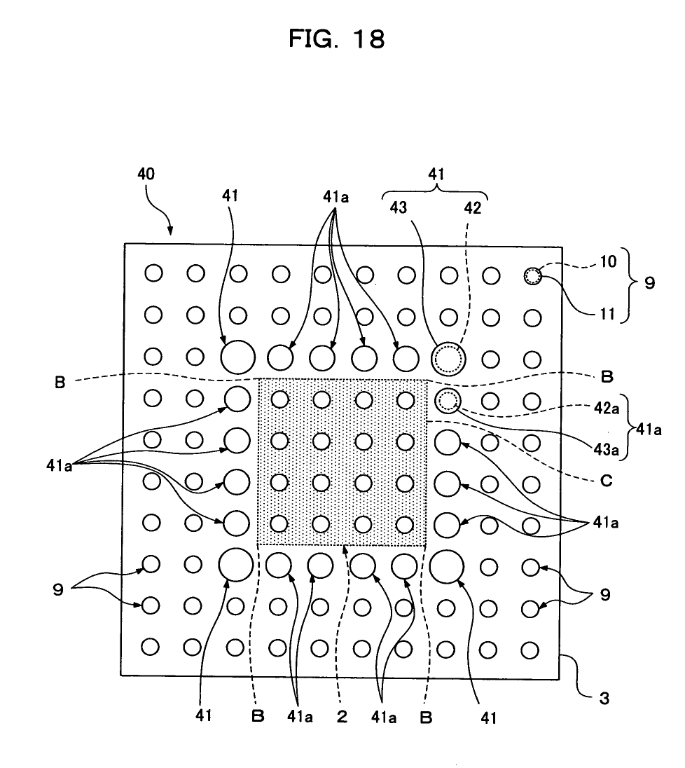

In a semiconductor device 40 of Embodiment 16 shown in FIG. 18, it is possible to prevent the solder joint of the first land 41 from being broken immediately below an outer end corner B of the semiconductor element 2 and prevent the solder joint of the second land 41a from being broken outside the line C.

### Embodiment 17

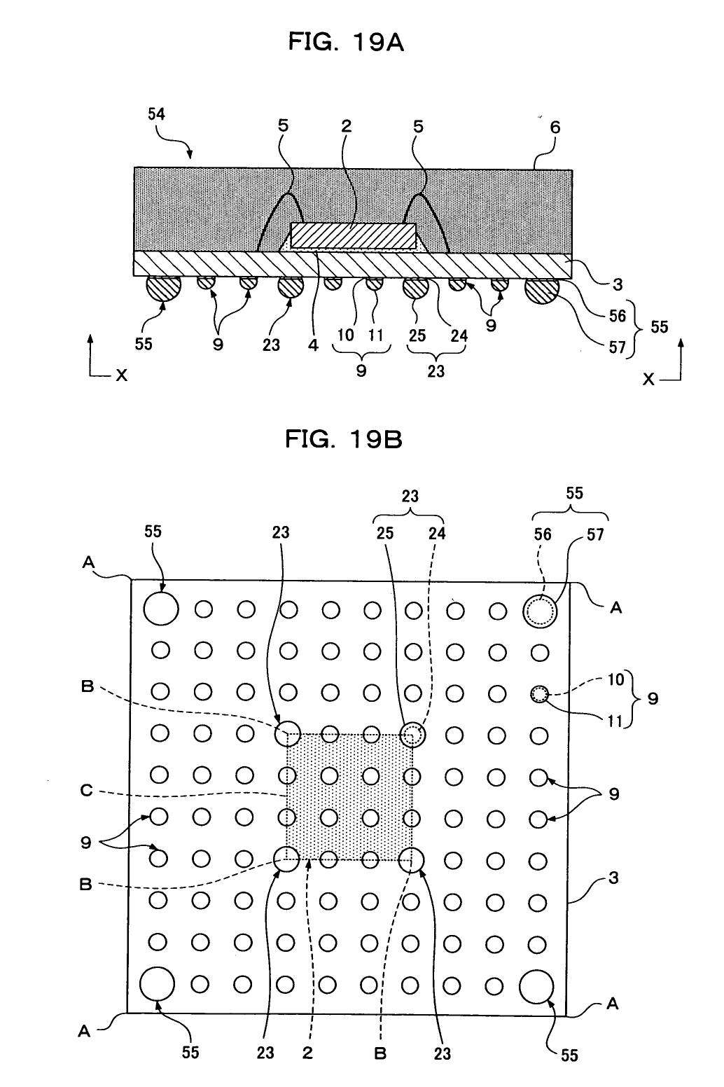

Embodiment 17 of the present invention will be described below. FIG. 19A is a front sectional view showing a semiconductor device 54. FIG. 19B is a plan view taken along line X-X of FIG. 19A.

In the semiconductor device 54 of Embodiment 17, third lands 55 on outermost corners A of the interposer circuit board 3 are larger in size than the other lands 9. To be specific, land terminals 56 of the third lands 55 are larger in diameter than land terminals 10 of the other lands 9, and solder balls 57 of the third lands 55 are larger in diameter and height than solder balls 11 of the other lands 9.

The other configurations and operations/working effects of Embodiment 17 are similar to those of Embodiment 1 (FIG. 1).

With this configuration, a solder joint to the land terminal 56 and the solder ball 57 of the third land 55 has a larger cross-sectional area than solder joints to the land terminals 10 and the solder balls 11 of the other lands 9, thereby reducing a stress which is applied to the solder joint of the third land 55 due to a difference in thermal expansion between the semiconductor device 54 and a printed wiring board 21. It is thus possible to prevent the solder joint of the third land 55 from being broken on the outermost corner A of the interposer circuit board 3.

Graph G2 (dotted line) of FIG. 3 shows the relationship between a distance from the center of the semiconductor device 54 and a stress of the solder joint. As compared with graph G1 (solid line) corresponding to Embodiment 1, the solder joint on the outermost corner A of the interposer circuit board 3 has a lower stress.

In Embodiment 17, the large third lands 55 are formed on the outermost corners A of the interposer circuit board 3 according to Embodiment 1 (FIG. 1). The large third lands 55 may be formed on the outermost corners A of the interposer circuit board 3 according to Embodiments 2 to 16, Thus, in Embodiments 2 to 16, it is possible to prevent the solder joint of the third land 55 from being broken on the outermost corner A of the interposer circuit board 3, in a similar manner to Embodiment 17.

### Embodiment 18

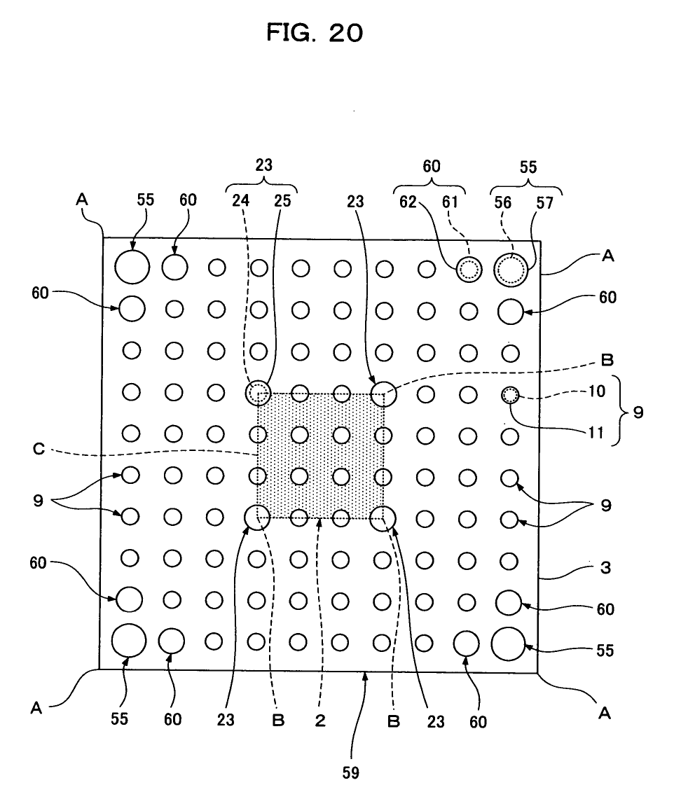

Embodiment 18 of the present invention will be described below. FIG. 20 shows an interposer circuit board 3 of a semiconductor device 59. The interposer circuit board 3 is viewed from the other surface.

In the semiconductor device 59 of Embodiment 18, fourth lands 60 adjacent to a third land 55 are larger in size than the other lands 9. To be specific, land terminals 61 of the fourth lands 60 are larger in diameter than land terminals 10 of the other lands 9, and solder balls 62 of the fourth lands 60 are larger in diameter and height than solder balls 11 of the other lands 9.

The other configurations and operations/working effects of Embodiment 18 are similar to those of Embodiment 17 (FIG. 19).

In Embodiment 17, another problem arises as follows: since the third land 55 is larger in size than the other lands 9, the size imbalance between the third land 55 and the adjacent lands 9 may cause stress concentration on the other lands 9 adjacent to the third land 55 and the solder joints of the adjacent lands 9 may be broken.

In contrast to Embodiment 17, as shown in FIG. 20, the fourth lands 60 on both sides of the third land 55 are larger in size than the other lands 9 in Embodiment 18, so that a solder joint to the land terminal 61 and the solder ball 62 of the fourth land 60 has a larger cross-sectional area than solder joints to the land terminals 10 and the solder balls 11 of the other lands 9. Thus in the event of stress concentration on the fourth land 60 adjacent to the third land 55, it is possible to prevent the solder joint of the fourth land 60 from being broken.

In Embodiment 18, the large third lands 55 are formed on outermost corners A of the interposer circuit board 3 according to Embodiment 1 (FIG. 1) and the large fourth lands 60 are formed on both sides of the third land 55. The large third lands 55 may be formed on the outermost corners A of the interposer circuit board 3 according to Embodiments 2 to 16 and the fourth lands 60 may be formed on both sides of the third land 55. Thus in Embodiments 2 to 16, in the event of stress concentration on the fourth land 60 adjacent to the third land 55, it is possible to prevent the solder joint of the fourth land 60 from being broken, in a similar manner to Embodiment 18.

### Embodiment 19

Embodiment 19 of the present invention will be described below. An interposer circuit board 3 is an organic substrate made of an organic resin. To be specific, the interposer circuit board 3 includes a substrate made of woven glass fabric saturated with epoxy resin, nonwoven glass fabric, or an aramid fiber.

Regarding this configuration, conventionally there has been a concern that a solder joint immediately below an outer end corners B of a semiconductor element 2 may be broken because the organic substrate is soft. However, even when using the interposer circuit board 3 which is an organic substrate, the configurations of Embodiments 1 to 18 make it possible to sufficiently prevent the solder joint from being broken immediately below the outer end corner B of the semiconductor element 2.

### Embodiment 20

In Embodiment 20 of the present invention, the thickness of an interposer circuit board 3 is 0.6 mm or less.

With this configuration, as the thickness of the interposer circuit board 3 decreases from 0.6 mm, the influence of a semiconductor element 2 increases which has high stiffness and a small thermal expansion coefficient. Thus, conventionally there has been a concern that particularly a solder joint immediately below an outer end corner B of the semiconductor element 2 may be broken. However, even when using the interposer circuit board 3 having a thickness of 0.6 mm or less, the configurations of Embodiments 1 to 18 make it possible to sufficiently prevent the solder joint from being broken immediately below the outer end corner B of the semiconductor element 2.

### Embodiment 21

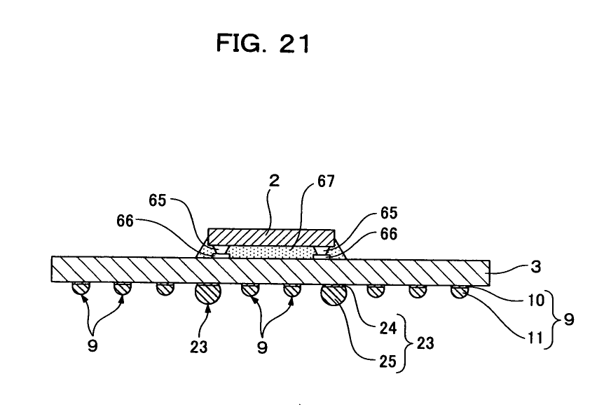

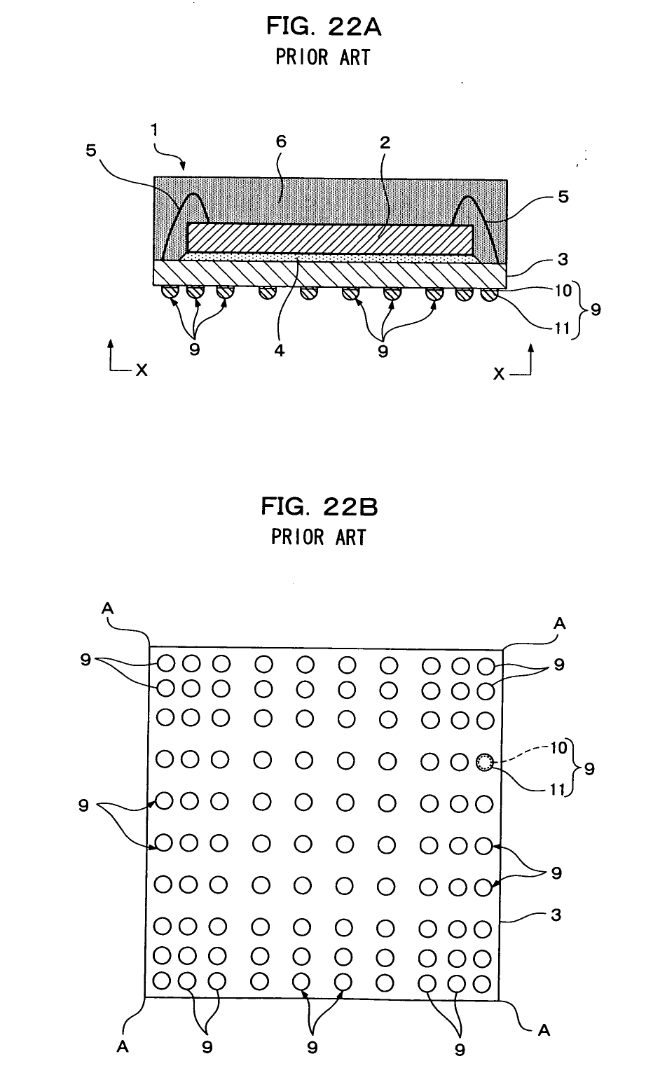

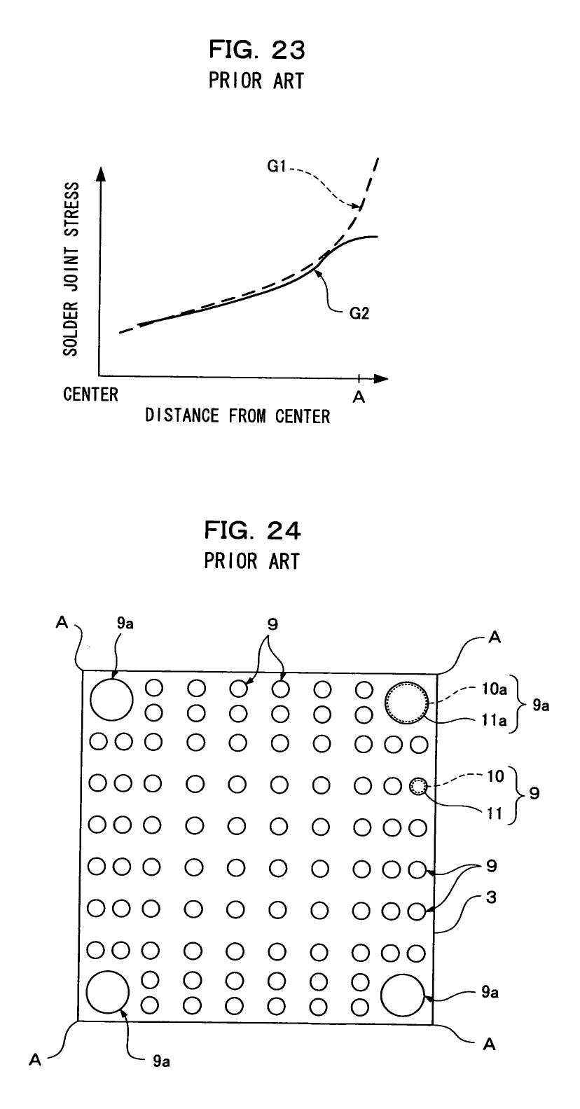

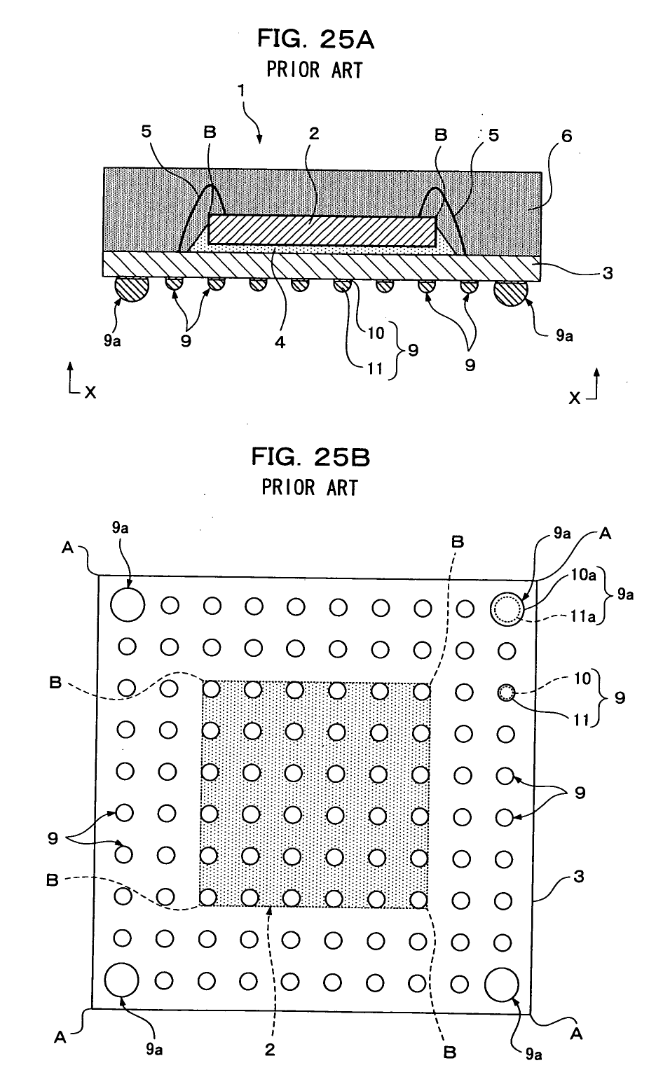

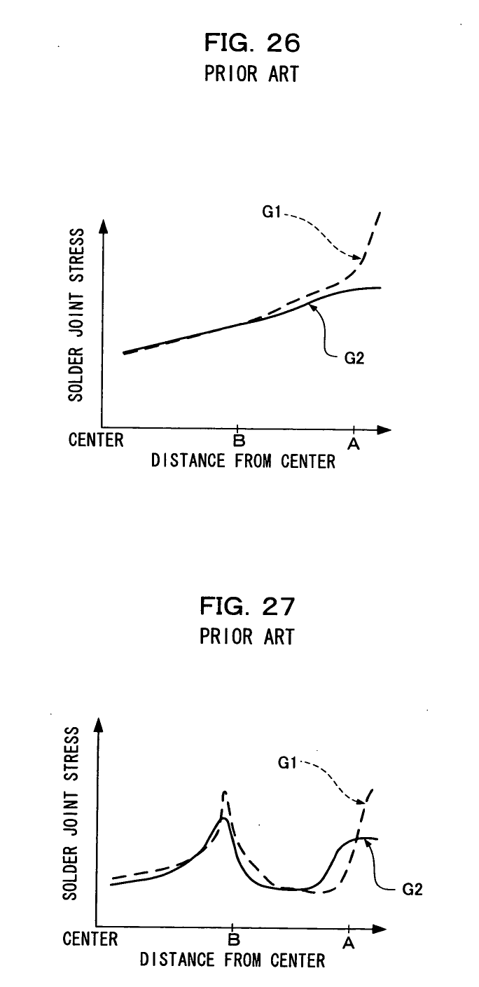

Embodiment 21 of the present invention will be described below. In Embodiments 1 to 20, the semiconductor element 2 and the interposer circuit board 3 are electrically connected to each other by wire bonding. In Embodiment 21, as shown in FIG. 21, a semiconductor element 2 and an interposer circuit board 3 are electrically connected to each other by a flip-chip method.

To be specific, metal bumps 65 are respectively formed on a plurality of electrode terminal pads of the semiconductor element 2 and the metal bumps 65 are bonded to electrode lands 66 of the interposer circuit board 3. An underfill resin 67 is applied between the semiconductor element 2 and the interposer circuit board 3, so that the semiconductor element 2 is fixed on one of the surfaces of the interposer circuit board 3.

The configuration in which the semiconductor element 2 d the interposer circuit board 3 are electrically connected each other by the flip-chip method is applicable to Embodiments 1 to 20, so that the same operations/working effects Embodiments 1 to 20 can be achieved.

As described above, the present invention is useful for providing a semiconductor device which includes a packaged miconductor element and ensures the reliability of desired solder joints while achieving narrow pitches and a high-density wiring circuit.

What is claimed is:

1. A semiconductor device comprising:
a wiring board;
a semiconductor element mounted on one of a front side and a back side of the wiring board; and
a plurality of lands for external connection, provided on the other side of the wiring board, the plurality of lands including a first land and other lands,
each of the lands comprising a land terminal formed on the wiring board and a spherical solder ball formed on the land terminal,
wherein the first land immediately below an outer end corner of the semiconductor element is larger in size than the other lands.

2. The semiconductor device according to claim 1, wherein a second land adjacent to the first land is larger in size than the other lands.

3. The semiconductor device according to claim 1, wherein the first land and the second land disposed on both sides of the first land are bonded into a large land having a larger size than the other lands.

4. The semiconductor device according to claim 1, wherein a second land other than a first land is also larger in size than the other lands, the second land being disposed immediately below a line of an outer edge of the semiconductor element.

5. The semiconductor device according to claim 1, wherein the wiring board is larger than the semiconductor element and a third land on an outermost corner of the wiring board is larger in size than the other lands.

6. The semiconductor device according to claim 5, wherein a fourth land adjacent to the third land is larger in size than the other lands.

7. The semiconductor device according to claim 1, wherein the wiring board is an organic substrate made of an organic resin.

8. The semiconductor device according to claim 1, wherein the wiring board has a thickness of not larger than 0.6 mm.

9. The semiconductor device according to claim 1, wherein the first land is electrically disconnected from the semiconductor element.

10. A semiconductor device comprising:
a wiring board;
a semiconductor element mounted on one of the front side and the back side of the wiring board; and
a plurality of lands for external connection, provided on the other side of the wiring board, the plurality of lands including a plurality of first lands and other lands,
each land comprising a land terminal formed on the wiring board and a spherical solder ball formed on the land terminal,
wherein the plurality of adjacent first lands immediately below a line of an outer edge of the semiconductor element are bonded into a land larger than the other lands.

11. The semiconductor device according to claim 10, wherein the wiring board is larger than the semiconductor element, and a third land on an outermost corner of the wiring board is larger in size than the other lands.

12. The semiconductor device according to claim 11, wherein a fourth land adjacent to the third land is larger in size than the other lands.

13. The semiconductor device according to claim 10, wherein the wiring board has a thickness of not larger than 0.6 mm.

14. The semiconductor device according to claim 10, wherein the large land is electrically disconnected from the semiconductor element.

15. A semiconductor device comprising:
a wiring board;
a semiconductor element mounted on one of the front side and the back side of the wiring board; and
a plurality of lands for external connection, provided on the other side of the wiring board, the plurality of lands including a plurality of first lands and other lands,
each land comprising a land terminal formed on the wiring board and a spherical solder ball formed on the land terminal,
wherein the plurality of first lands disposed near outer end corners of the semiconductor element and inside or outside a line of an outer edge of the semiconductor element are larger in size than the other lands.

16. The semiconductor device according to claim 15, wherein the wiring board is larger than the semiconductor element, and a third land on an outermost corner of the wiring board is larger in size than the other lands.

17. The semiconductor device according to claim 16, wherein a fourth land adjacent to the third land is larger in size than the other lands.

18. The semiconductor device according to claim 15, wherein the wiring board has a thickness of not larger than 0.6 mm.

19. The semiconductor device according to claim 15, wherein the first land is electrically disconnected from the semiconductor element.
